(19) United States
(12) Patent Application Publication
(10) Pub. No.: US 2024/0189780 A1
(43) Pub. Date: Jun. 13, 2024

(54) DISSOLVED AMMONIA DELIVERY SYSTEM AND METHODS OF USE

(71) Applicant: MKS Instruments, Inc., Andover, MA (US)

(72) Inventors: Felix Groitl, Berlin (DE); Johannes Seiwert, Berlin (DE); Christiane Le Tiec, Berlin (DE)

(21) Appl. No.: 18/079,338

(22) Filed: Dec. 12, 2022

Related U.S. Application Data
(60) Provisional application No. 63/289,438, filed on Dec. 14, 2021.

(51) Int. Cl. B01F 23/232; B01F 23/237

(52) U.S. Cl. CPC B01F 23/2323; B01F 23/2376

(57) ABSTRACT

The present invention concerns a dissolved ammonia delivery system, comprising at least one ultrapure water source configured to provide ultrapure water, at least one carrier gas source configured to provide at least one carrier gas, at least one ammonia (NH3) source configured to provide NH3, at least one ammonia saturation module having at least one of one main flow pathway and one bypass flow pathway in communication with the main flow pathway if both main flow pathway and bypass flow pathway are comprised by said at least one ammonia saturation module, the main flow pathway if present configured to have ultrapure water from the ultrapure water source flowed therethrough, the bypass flow pathway configured to receive at least a portion of the ultrapure water from the main flow pathway, if present, to form at least one ultrapure water bypass flow within the bypass flow pathway, wherein the carrier gas and NH3 introduced into the ultrapure water bypass flow resulting in NH3 dissolving in the ultrapure water bypass flow.

### CROSS-REFERENCE TO RELATED APPLICATIONS

This patent application claims the benefit of U.S. Prov. Ser. No. 63/289,438 filed on Dec. 14, 2021, application that is incorporated by reference herein.

### BACKGROUND OF THE INVENTION

### Field of the Invention

This invention relates to a system for delivering dissolved ammonia, and a method for producing dissolved ammonia.

### Description of Related Art

Presently, dissolved ammonia is used in a number of semiconductor processing applications. For example, in some wafer processing applications, low concentration dissolved ammonia is used to obtain a desired conductivity, and so to avoid undesirable and destructive electrical discharges which potentially could result in the destruction of the semiconductor wafer being processed or structures formed on the semiconductor wafer. Dissolved ammonia is especially used to avoid cupper corrosion.

Numerous methods of providing dissolved ammonia are currently being employed. For example, in some applications high concentration liquid ammonia hydroxide is diluted with deionized water. While this method has proven to be somewhat useful in the past, a number of shortcomings have been identified. For example, high concentration ammonia poses a health hazard as high concentration ammonia (i.e. in excess of 300 ppm) is immediately dangerous to health. For example, ammonia has been shown to cause severe irritation to the lungs, eyes, and skin.

In contrast, gaseous ammonia may be directly mixed into deionized water to produce dissolved ammonia. FIG. 1 shows an embodiment of a prior art system for producing dissolved ammonia. As shown, the system 1 includes a contacting system 3, that is typically embodied by a packed column or packed tower type contactor, in communication with an ultrapure water source 5, hereinafter UPW source 5, via an UPW source conduit 7. One or more valve devices 9 and/or one or more meters 11 is used to control and monitor the flow to the contactor 3. A carrier gas source 15 is configured to deliver at least one carrier gas (e.g. N2, O2, or noble gas) to the contactor 3 via a gas conduit 33. The gas is inserted before the contactor. In addition, an ammonia source 25 is configured to provide ammonia (NH3) to the contactor via the gas conduit 33. One or more valves or flow control devices 19, 29 is used to control and monitor the flow of the carrier gas and ammonia to the contactor 3. The ultrapure water, carrier gas, and highly soluble ammonia is introduced and mixed within the contactor 3. Thereafter, the dissolved ammonia 51 may be flowed from the contactor 3 via a dissolved ammonia conduit 53. In addition, waste products 61 may be drained from the contactor 3 via a drain conduit 63. Lastly, outgases 43 may be removed from the contactor 3 via an outgas conduit 41.

While this gaseous dissolved ammonia delivery system has proved useful, the system tends to produce an excess of undesirable bubbles due to carrier gas saturation. The presence of too many bubbles has the affects the distribution of ammonia on the wafer. Further, often larger pumps are used within the system to mitigate the presence of bubbles. Unfortunately, the inclusion of larger pumps results in higher system costs and an unwanted increase in the temperature of the dissolved ammonia outputted from the contactor.

In light of the foregoing, there is an ongoing need for an efficient system and method for producing dissolved ammonia.

### BRIEF SUMMARY OF THE INVENTION

The present invention has been conceived and developed aiming to provide solutions to the above stated objective technical needs, as it will be evidenced in the following description.

In accordance with an embodiment of the present invention is proposed a dissolved ammonia delivery system, comprising at least one ultrapure water source configured to provide ultrapure water, at least one carrier gas source configured to provide at least one carrier gas, at least one ammonia (NH3) source configured to provide NH3, at least one ammonia saturation module having at least one of one main flow pathway and one bypass flow pathway in communication with the main flow pathway if both main flow pathway and bypass flow pathway are comprised by said at least one ammonia saturation module, the main flow pathway if present configured to have ultrapure water from the ultrapure water source flowed therethrough, the bypass flow pathway configured to receive at least a portion of the ultrapure water from the main flow pathway, if present, to form at least one ultrapure water bypass flow within the bypass flow pathway, wherein the carrier gas and NH3 introduced into the ultrapure water bypass flow resulting in NH3 dissolving in the ultrapure water bypass flow.

In accordance with further aspects of the present invention, the carrier gas source is configured to deliver at least one carrier gas to a contactor via a gas conduit, and the carrier gas source is in communication with the NH3 saturation module via at least one carrier gas conduit and/or at least one NH3/carrier gas conduit. The ammonia source is configured to provide ammonia to the contactor via the gas conduit. The at least one carrier gas source is in communication with the NH3 saturation module via at least one carrier gas conduit and/or at least one NH3/carrier gas conduit. The ammonia saturation module comprises a saturation region, where ammonia is directly diluted in an ultrapure water UPW bypass flow. The NH3 saturation module comprises a semi-permeable or permeable membrane or structure positioned within the flow pathway passage proximate to the junction of the ammonia conduit and the flow pathway. The ammonia is either gaseous or non-gaseous.

In accordance with another embodiment of the present invention is proposed a method of producing dissolved ammonia via a delivery system, comprising: coupling at least a carrier gas source in fluid communication with an ammonia saturation module, said carrier gas source providing ammonia to said ammonia saturation module, controlling through an optional main flow pathway and at least one bypass flow pathway, comprised by the ammonia saturation module, an ultrapure water flow from an ultrapure water source, wherein the bypass flow pathway being in fluid communication with at least one of said carrier gas source and an ammonia source, introducing into an ultrapure bypass flow within the bypass flow pathway bubbles formed by at least one of the carrier gas sources to form dissolved ammonia, and, optionally, recombining said dissolved ammonia with said ultrapure main flow and directing said dissolved ammonia to a dissolved ammonia conduit to form a dissolved ammonia output.

In accordance with further aspects of the present invention, the method further comprises outgassing the carrier gas to produce one or more gas outputs. The ammonia gas is directly diluted in the ultrapure water bypass flow away from a nitrogen saturation area. The ultrapure water flow reacting with the ammonia within the carrier gas bubbles forms the highly soluble ammonia gas dissolving within the ultrapure water flow.

### BRIEF DESCRIPTION OF THE SEVERAL VIEWS OF THE DRAWING(S)

The above and other aspects, features and advantages of the present invention will become more apparent from the subsequent description thereof, presented in conjunction with the following drawings, wherein:

FIG. 1 is a graphical illustration of a system for producing dissolved ammonia, as known from the prior art;

FIG. 2 is a graphical illustration of a system for producing dissolved ammonia, in accordance with an embodiment of the present invention;

FIG. 3 is a representation of a saturation module, in accordance with one embodiment of the present invention;

FIG. 4 is another representation of a dissolved ammonia delivery system, in accordance with the present invention;

FIGS. 4-6 show various embodiments of a saturation region of the ammonia saturation module, where the ammonia is directly diluted in the UPW bypass flow;

FIG. 7 shows another embodiment of a dissolved ammonia delivery system, in accordance with the present invention;

FIG. 8 shows a further embodiment of a dissolved ammonia delivery system, in accordance with the present invention;

FIG. 9 shows an alternate embodiment of a NH3 saturation module, in accordance with the present invention;

FIG. 10 shows a further yet element of the delivery system in accordance with the present invention; and

FIG. 11 shows a flow chart concerning a method of producing dissolved ammonia.

### DETAILED DESCRIPTION OF THE INVENTION

Exemplary embodiments are described below with reference to the accompanying drawings. Unless otherwise expressly stated, in the drawings the sizes, positions, etc., of components, features, elements, etc., as well as any distances therebetween, are not necessarily to scale, and may be disproportionate and/or exaggerated for clarity.

The terminology used herein is for the purpose of describing particular example embodiments only and is not intended to be limiting. As used herein, the singular forms “a,” “an” and “the” are intended to include the plural forms as well, unless the context clearly indicates otherwise. It should be recognized that the terms “comprises” and/or “comprising.” when used in this specification, specify the presence of stated features, integers, steps, operations, elements, and/or components, but do not preclude the presence or addition of one or more other features, integers, steps, operations, elements, components, and/or groups thereof. Unless otherwise specified, a range of values, when recited, includes both the upper and lower limits of the range, as well as any sub-ranges therebetween. Unless indicated otherwise, terms such as “first,” “second,” etc., are only used to distinguish one element from another. For example, one node could be termed a “first mirror” and similarly, another node could be termed a “second mirror”, or vice versa.

Unless indicated otherwise, the term “about,” “thereabout,” etc., means that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those skilled in the art.

Many of the embodiments described in the following description share common components, devices, and/or elements. Like named components and elements refer to like named elements throughout. For example, many of the embodiments described in the following detailed description include at least one ultrapure water source (hereinafter UPW source), carrier gas source, ammonia gas source, main flow pathway, bypass flow pathway, and the like. Thus, the same or similar named components or features may be described with reference to other drawings even if they are neither mentioned nor described in the corresponding drawing. Also, even elements that are not denoted by reference numbers may be described with reference to other drawings.

Many different forms and embodiments are possible without deviating from the spirit and teachings of this disclosure and so this disclosure should not be construed as limited to the example embodiments set forth herein. Rather, these example embodiments are provided so that this disclosure will be thorough and complete, and will convey the scope of the disclosure to those skilled in the art.

The present application discloses various systems and methods for providing or producing dissolved ammonia. In one particular embodiment, the systems disclosed herein may be configured to provide dissolved ammonia based on dissolving gaseous ammonia in at least one flow of ultrapure water without requiring a contactor, as it is the requirement in prior art systems.

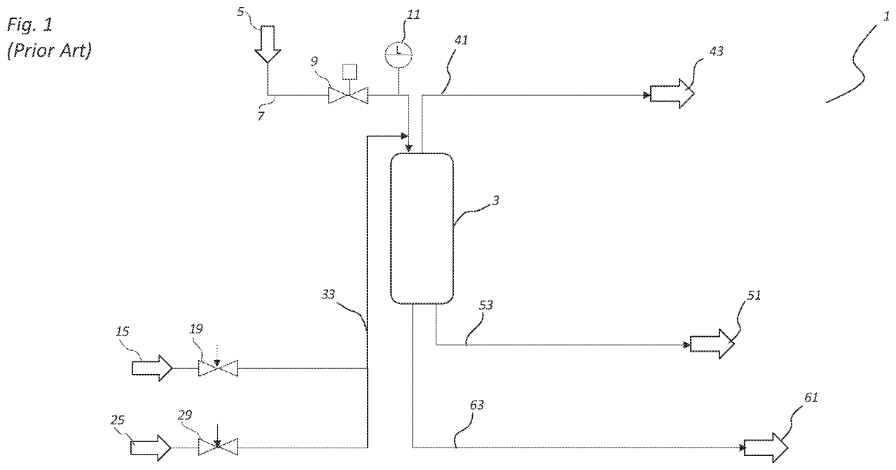

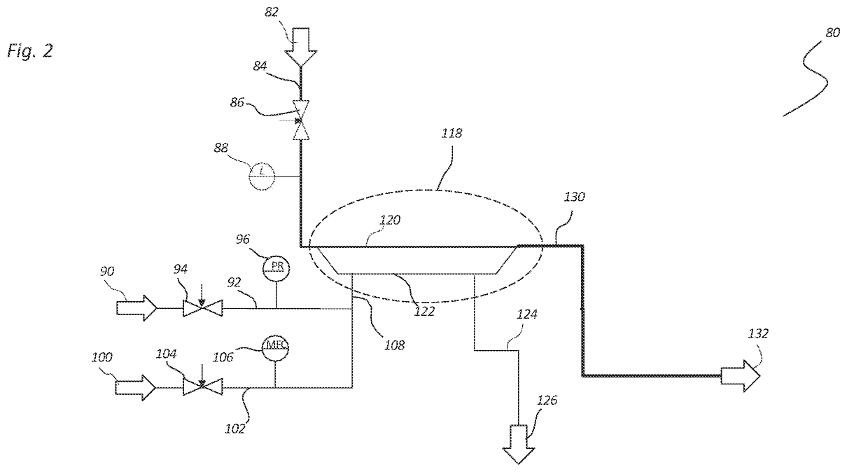

FIG. 2 shows an embodiment of a dissolved ammonia delivery system. Unlike prior art ammonia delivery systems, the dissolved ammonia delivery systems disclosed in the present application eliminate the need for a contactor (see FIG. 1, contactor 3), thereby reducing system cost and complexity. As shown, the ammonia delivery system 80 includes at least one UPW source 82 having at least one UPW source conduit 84 in fluid communication therewith. At least one valve device or flow control device 86 may be positioned on or in communication with the UPW source conduit 84. In addition, at least one meter, controller, or indicator 88 may be in communication with at least one of the UPW source 82, UPW source conduit 84, and/or the valve device 86 (if present). As shown, the UPW source 82 is in communication with at least one NH3 saturation module 118 via the UPW source conduit 84. The system of FIG. 2 may optionally include a pump as well, although the presence of the pump is not required, and as such it is not represented in FIG. 2.

Referring again to FIG. 2, at least one carrier gas source 90 may be in communication with the NH3 saturation module 118 via at least one carrier gas conduit 92 and/or at least one NH3/carrier gas conduit 108. In the illustrated embodiment, the carrier gas source 90 is coupled to at least one carrier gas conduit 92 which is coupled to the NH3/carrier gas conduit 108, although those skilled in the art will appreciate that the carrier gas source 90 may be in fluid communication with the NH3 saturation module 118 via any variety of conduits. Optionally, at least one valve or flow controller 94 and/or meter or indicator 96 may be used to control and monitor the flow of carrier gas from the carrier gas source 90 to the NH3 saturation module 118. Optionally, at least one pressure regulator (not shown) may be used in addition to or in place of at least one of the flow controller 94 and meter 96. Exemplary carrier gases used in the present system include, without limitations, N2, O2, and any variety of noble gases and the like.

As shown in FIG. 2, at least one ammonia source 100 may be in communication with the NH3 saturation module 118 via at least one carrier ammonia conduit 102 and/or at least one NH3/carrier gas conduit 108. In one embodiment, the ammonia source 100 is configured to provide gaseous ammonia to the NH3 saturation module 118. As shown, the ammonia source 100 is coupled to at least one ammonia conduit 102 which, in turn, is coupled to the NH3/carrier gas conduit 108, although those skilled in the art will appreciate that the ammonia source 100 may be in fluid communication with the NH3 saturation module 118 via any variety of conduits. At least one valve or flow controller 104 and/or mass flow meter 106 may be used to control and monitor the flow of gaseous ammonia from the ammonia source 100 to the NH3 saturation module 118. Again, optionally, at least one pressure regulator (not shown) could be used in addition to or in place of the flow controller 104 and the mass flow meter 106.

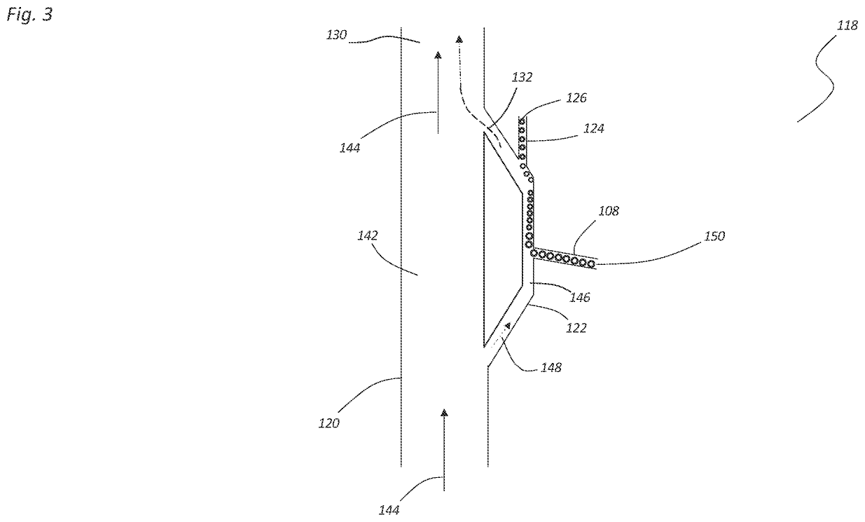

Referring again to FIGS. 2 and 3, the NH3 saturation module 118 includes at least one main flow pathway 120 and at least one bypass flow pathway 122, or alternatively may include only a bypass flow pathway 122. The main flow pathway 120 and bypass flow pathway 122 are configured to have ultrapure water from the UPW source 82 flowed therethrough. As shown in FIG. 3, the main flow pathway 120 defines at least one main flow pathway passage 142 configured to receive an UPW flow 144 therein. Similarly, the bypass flow pathway 122 defines at least one bypass flow pathway passage 146 configured to flow a portion of the UPW flow 144 from the main flow pathway 120 therein, thereby forming at least one UPW bypass flow 148. In the illustrated embodiment, the bypass flow pathway 122 is in fluid communication with at least one of the carrier gas source 90 and the ammonia source 100 via the at least one NH3/carrier gas conduit 108. Bubbles 150 formed by at least one of the carrier gas/ammonia gas from the NH3/carrier gas conduit 108 are introduced into the UPW bypass flow 148 within the bypass pathway 122 resulting in the highly soluble ammonia gas dissolving the UPW bypass flow 148, thereby forming dissolved ammonia 132. The dissolved ammonia 132 is then recombined with the UPW main flow 144 and directed to a dissolved ammonia conduit 130 configured to form a dissolved ammonia output 132. In addition, the carrier gas may be outgassed via at least one outgas conduit 124 to produce one or more outgas outputs 126. In an alternative embodiment of the invention, the complete liquid flow may be captured by the bypass line, and the presence of the main flow line is not mandatory, but the main flow line is optional. Splitting of the flow rate and having a bypass line lowers the carrier gas saturation within the process liquid, and reduces the formation of unwanted bubbles.

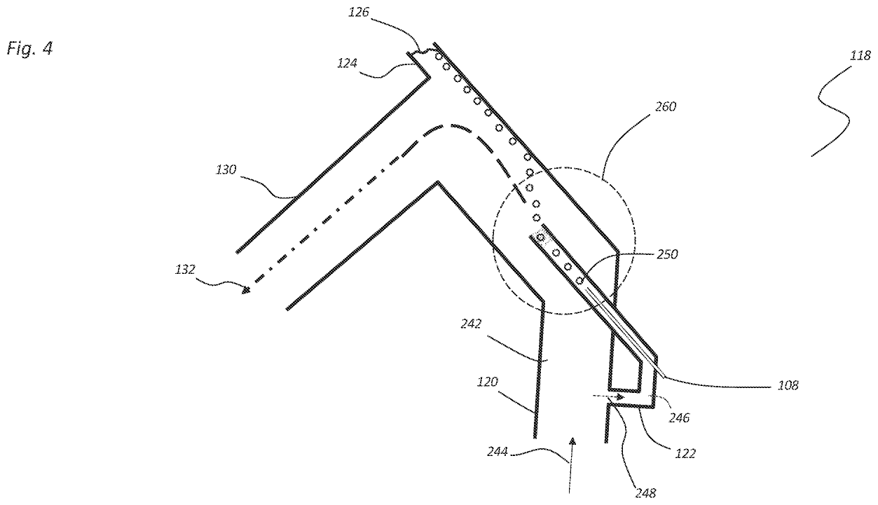

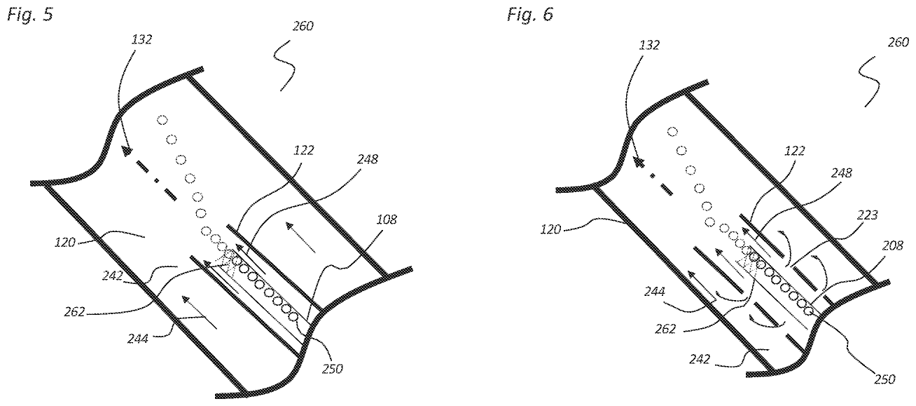

FIG. 4 is another representation of a dissolved ammonia delivery system, in accordance with the present invention. Those skilled in the art will appreciate that similarly named and numbered components perform similar functions to the previous embodiment. As shown, the dissolved ammonia delivery system 118 includes at least one main flow pathway 120 defining at least one main flow passage 242 therein. The main flow passage 242 may be configured to receive at least one ultrapure water flow 244 therein. In addition, the dissolved ammonia delivery system 118 further includes at least one bypass flow pathway 122 defining at least one bypass flow passage 246. As shown, the bypass flow passage 246 is in fluid communication with the main flow passage 242. Thus, the bypass flow passage 246 may be configured to have at least one UPW bypass flow 248 directed therethough.

As shown in FIG. 4, at least a portion of the NH3/carrier gas conduit 108 may be positioned within or in fluid communication with the bypass flow passage 246 formed in the bypass flow pathway 122. Further, the NH3/carrier gas conduit 108 is in fluid communication with at least one of the carrier gas source 90 and/or the ammonia source 100 (See FIG. 2). Like the previous embodiment, bubbles 250 formed by at least one of the carrier gas/ammonia gas from the NH3/carrier gas conduit 108 are introduced into the UPW bypass flow 248 within the bypass pathway 122 resulting in the highly soluble ammonia gas dissolving in the UPW bypass flow 248, thereby forming dissolved ammonia 132. The dissolved ammonia 132 is then recombined with the UPW main flow 244 and directed to at least one dissolved ammonia conduit 130 configured to form at least one dissolved ammonia output 132. In addition, the carrier gas may be outgassed via at least one outgas conduit 124 to produce one or more outgas outputs 126.

FIGS. 4-6 show various embodiments of the saturation region 260 of the ammonia saturation module 118 where the ammonia is directly diluted in the UPW bypass flow 248. As shown in FIG. 5, the bypass pathway 122 is positioned within the main flow pathway 120. The NH3/carrier gas conduit 108 is positioned within the bypass pathway 122 configured to emit or otherwise introduce ammonia gas 250 from the ammonia source 100 (See FIG. 2) into the UPW bypass flow 248 to produce a dissolved ammonia output 132. As shown in FIG. 5, the ammonia gas from the NH3/carrier gas conduit 108 is directly diluted in the UPW bypass flow 248 away from the N2 saturation area 262, thereby drastically reducing bubbles in the dissolved ammonia output 132. In contrast, FIG. 6 shows an alternate embodiment of the bypass pathway 122 having one or more apertures or orifices 223 formed thereon proximate to the N2 saturation area 262 within the saturation region 260. Like the previous embodiment, ammonia gas from the NH3/carrier gas conduit 108 is directly diluted in the UPW bypass flow 248 away from the N2 saturation area 262, thereby drastically reducing bubbles in the dissolved ammonia output 132.

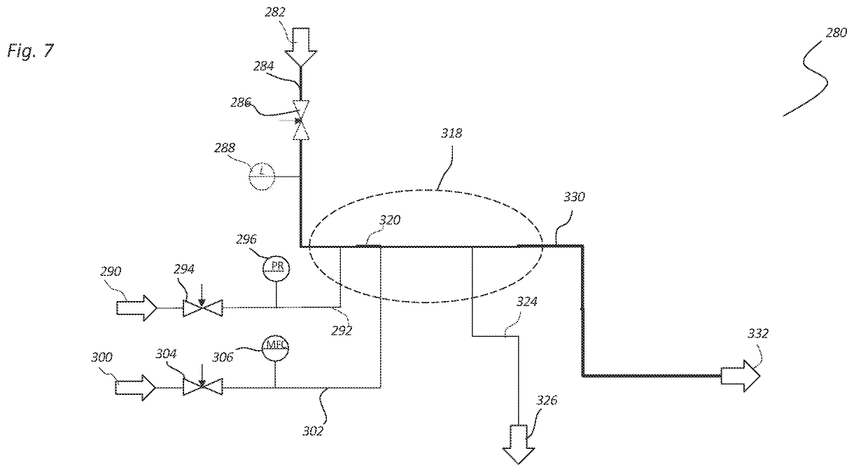

FIG. 7 shows another embodiment of a dissolved ammonia delivery system. The ammonia delivery system 280 includes at least one UPW source 282 having at least one UPW source conduit 824 in fluid communication therewith. At least one valve device or flow control device 286 may be positioned on or in communication with the UPW source conduit 284. In addition, at least one meter, controller, or indicator 288 may be in communication with at least one of the UPW source 282, UPW source conduit 284, and/or the valve device 286 (if present). As shown, the UPW source 282 is in communication with at least one NH3 saturation module 318 via the UPW source conduit 284.

Referring again to FIG. 7, at least one carrier gas source 290 may be in communication with the NH3 saturation module 318 via at least one carrier gas conduit 292. Optionally, at least one valve or flow controller 294 and/or meter or indicator 296 may be used to control and monitor the flow of carrier gas from the carrier gas source 290 to the NH3 saturation module 318. Optionally, one or more pressure regulators (not shown) may be used in addition to or in place of the flow controller 294 and/or the meter 296. Exemplary carrier gases used in the present system include, without limitations, N2, O2, and any variety of noble gases and the like.

As shown in FIG. 7, at least one ammonia source 300 may be in communication with the NH3 saturation module 318 via at least one ammonia conduit 302. In one embodiment, the ammonia source 300 is configured to provide gaseous ammonia to the NH3 saturation module 318. At least one valve or flow controller 304 and/or mass flow meter 306 may be used to control and monitor the flow of gaseous ammonia from the ammonia source 300 to the NH3 saturation module 318. Optionally, at least one pressure regulator (not shown) may be used in combination with or in place of the flow controller 304 and/or mass flow meter 306.

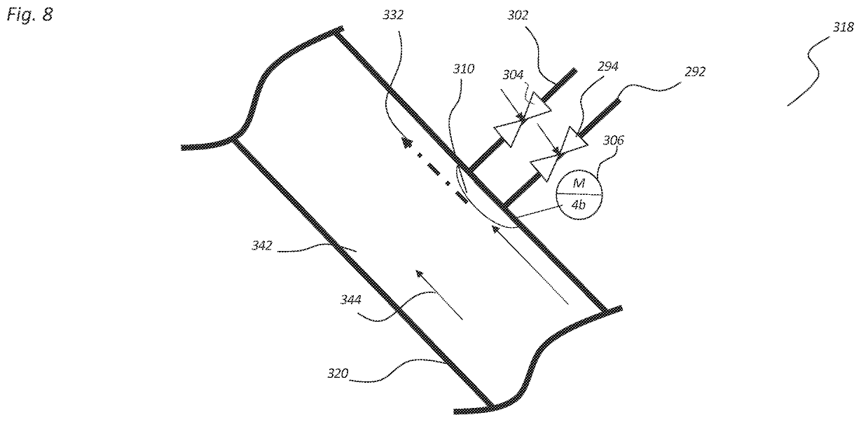

Referring to FIGS. 7-9, the NH3 saturation module 318 includes at least one flow pathway 320. The flow pathway 320 is configured to have ultrapure water from the UPW source 282 flowed therethrough. As shown in FIG. 7, the flow pathway 320 defines at least one flow pathway passage 342 configured to receive an UPW flow 344 therein. In the illustrated embodiment, the carrier gas conduit 292 is in fluid communication with flow pathway passage 342 and is configured to provide at least one carrier gas to the UPW flow 344. Similarly, the ammonia conduit 302 is in communication with the flow pathway 342 and configured to provide ammonia gas to the UPW flow 344. As shown, at least one carrier gas bubble 310 is formed and maintained within the flow pathway passage 342. As such, at least one valve or flow control device 294 may be used to regulate or otherwise control the presence, size, and volume of the carrier gas bubble 310 within the UPW flow 344. Gaseous ammonia from the ammonia source 300 is introduced into the carrier gas bubble 310. The UPW flow 344 reacts with the ammonia within the carrier gas bubble 310 which results in the highly soluble ammonia gas dissolving within the UPW flow 344 thereby forming dissolved ammonia 332. The dissolved ammonia 332 is directed to a dissolved ammonia conduit 330. In addition, the carrier gas may be outgassed via at least one outgas conduit 324 to produce one or more outgas outputs 326.

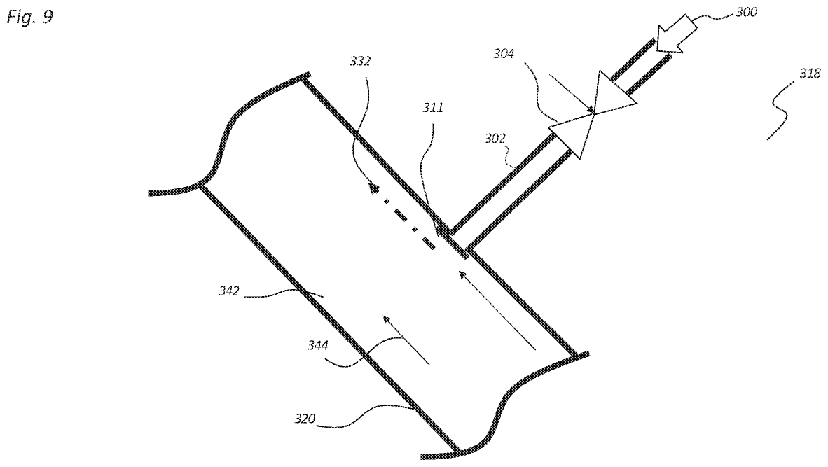

In an alternate embodiment, FIG. 9 shows an embodiment of a NH3 saturation module 318 shown in FIG. 7. As shown, the NH3 saturation module 318 includes a semi-permeable or permeable membrane or structure 311 positioned within the flow pathway passage 342 proximate to the junction of the ammonia conduit 304 and the flow pathway 320. During use, a UPW flow 344 is established within the flow pathway passage 342. Gaseous ammonia from the ammonia source 300 (See FIG. 7) is controllably introduced into the UPS flow 344 via the ammonia conduit 304 and the membrane 311. One or more valve members or flow controllers may be used to control the flow of ammonia to the flow pathway passage. The UPW flow 344 reacts with the highly soluble ammonia thereby producing dissolved ammonia 332.

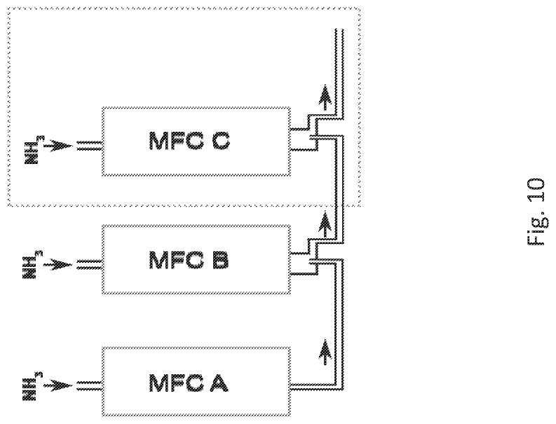

FIG. 10 shows a further yet element of the delivery system in accordance with the present invention.

In the ammonia systems available in the art, nitrogen was used to flush out the ammonia from the ammonia delivery system, in order to have a quicker response from the ammonia delivery system. A pressure controller was present, situated on a left side the mass flow controller, that flushed out all the mass flow controllers to remove the ammonia from the system. But, if a set point change or a flow change occurs, there is a need to transport the ammonia quicker to the contacting system.

A different approach to flush the ammonia from the delivery system, is illustrated in FIG. 10, wherein differently sized mass flow controllers are placed in serial approach, with the mass flow controller A being the largest, and the mass flow controller C being the smallest. The illustrated arrangement comprising three such mass flow controllers placed in series is only an exemplary arrangement, and any number of such controllers may be used. With the illustrated arrangement, it is the ammonia itself that is used to flush the system, and more precisely, it is the ammonia that is used to flush out the smaller mass flow controllers to improve the dynamic of the system. More specifically, the larger mass flow controllers always flush out the smaller mass flow controllers to improve the dynamic of the system. For example, at system startup, the system may have rests of air or nitrogen inside, and a high dynamic between these. For quick system start up, first every unwanted gas should be flushed out from the system, and therefore the flush out starts with MFC A, which has a very high magnitude of ammonia flow to flush out. This operation is only used for starting up the ammonia delivery system. All the other volumes of the system need to always have ammonia inside the system. The employment of such a flushing system ensures that the ammonia delivery system always operates at a constant pressure. This is very important, that the gas area is always kept at a constant pressure. The optimal system's functionality depends on the fact that the pressure or relative pressures within the system are kept stable, especially in the gas part, because otherwise the dynamic of the system is altered.

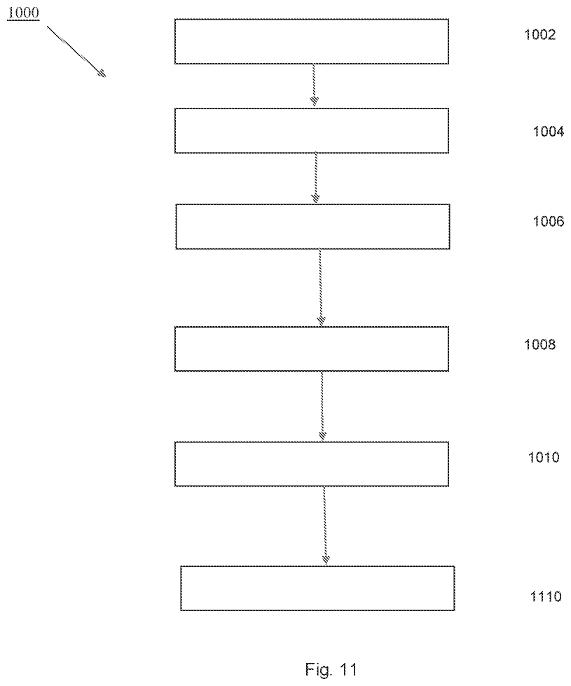

FIG. 11 shows a flow chart concerning a method of producing dissolved ammonia. In accordance with the present invention, is proposed a method of producing dissolved ammonia 1000. The method comprises the step 1002, of coupling at least a carrier gas source in fluid communication with an ammonia saturation module, so that said carrier gas source provides ammonia to said ammonia saturation module. The method further comprises a step 1004 consisting of controlling through an optional main flow pathway and at least one bypass flow pathway, comprised by the ammonia saturation module, ultrapure water flow an ultrapure source. The bypass flow pathway is in fluid communication with at least one of said carrier gas source and an ammonia source. The method 1000 further comprises introducing into an ultrapure bypass flow within the bypass flow pathway bubbles formed by at least one of the carrier gas sources to form dissolved ammonia, in a step 1006. The method 1000 further comprises, optionally, in a step 1110, recombining said dissolved ammonia with said ultrapure main flow and directing said dissolved ammonia to a dissolved ammonia conduit to form a dissolved ammonia output.

The method 1000 may further comprise outgassing the carrier gas, in a step 1110, to produce one or more gas outputs. The ammonia gas may be directly diluted in the ultrapure water bypass flow away from a nitrogen saturation area. The ultrapure water flow reacts with the ammonia within the carrier gas bubbles to form the highly soluble ammonia gas dissolving within the ultrapure water flow.

As discussed in detail above, the solutions presented by the present invention consist of systems with a simpler configuration compared with the systems known from the prior art, that are able to provide systems with reduced cost without sacrificing their performance. The saturation of the carrier gas is minimized in the systems of the present invention, and as a result bubbles and outgassing at the Point-of-Use are minimized. At the same time, the use in the systems of the present invention of a static bypass keeps the system at any time away from the carrier gas saturation point. Further, the carrier gas consumption of the unit is reduced. The systems of the present invention use a constant water pressure/gas pressure setup to achieve a high dynamic and at the same time stable behavior. Further, the temperature increase is reduced by usage of a smaller pump system.

The solutions of the present invention are characterized by the fact that their configuration does not require a contactor. As such the amount of carrier gas used is minimized. By using the bypass, the dissolved ammonia is directly diluted, moving away from the carrier gas saturation point, and as a result the amount of bubbles is drastically reduced or eliminated. Further, since the use of big pumps is avoided, no drastic temperature increases take place. All these advantages lead to significant cost savings regarding the systems and its operational costs, but with no performance sacrifice.

The embodiments disclosed herein are illustrative of the principles of the invention. Other modifications may be employed which are within the scope of the invention. Accordingly, the devices disclosed in the present application are not limited to that precisely as shown and described herein.

What is claimed:

1. A dissolved ammonia delivery system, comprising:
at least one ultrapure water source configured to provide ultrapure water;
at least one carrier gas source configured to provide at least one carrier gas;
at least one ammonia (NH3) source configured to provide NH3;
at least one ammonia saturation module having at least one of one main flow pathway and one bypass flow pathway in communication with the main flow pathway if both main flow pathway and bypass flow pathway are comprised by said at least one ammonia saturation module, the main flow pathway if present configured to have ultrapure water from the ultrapure water source flowed therethrough,
the bypass flow pathway configured to receive at least a portion of the ultrapure water from the main flow pathway if present to form at least one ultrapure water bypass flow within the bypass flow pathway,
wherein the carrier gas and NH3 introduced into the ultrapure water bypass flow resulting in NH3 dissolving in the ultrapure water bypass flow.

2. The system of claim 1, wherein said carrier gas source is configured to deliver at least one carrier gas to a contactor via a gas conduit, and
wherein said carrier gas source is in communication with the NH3 saturation module via at least one carrier gas conduit and/or at least one NH3/carrier gas conduit.

3. The system of claim 2, wherein said ammonia source is configured to provide ammonia to said contactor via the gas conduit.

4. The system of claim 1, wherein said at least one carrier gas source is in communication with the NH3 saturation module via at least one carrier gas conduit and/or at least one NH3/carrier gas conduit.

5. The system of claim 1, wherein said ammonia saturation module comprising a saturation region where ammonia is directly diluted in an ultrapure water UPW bypass flow.

6. The system of claim 1, wherein the NH3 saturation module comprises a semi-permeable or permeable membrane or structure positioned within the flow pathway passage proximate to the junction of the ammonia conduit and the flow pathway.

7. A method of producing dissolved ammonia via a delivery system, comprising:
coupling at least a carrier gas source in fluid communication with an ammonia saturation module, said carrier gas source providing ammonia to said ammonia saturation module;
controlling through an optional main flow pathway and at least one bypass flow pathway, comprised by the ammonia saturation module, an ultrapure water flow from an ultrapure water source;
wherein the bypass flow pathway being in fluid communication with at least one of said carrier gas source and an ammonia source;
introducing into an ultrapure bypass flow within the bypass flow pathway bubbles formed by at least one of the carrier gas sources to form dissolved ammonia;
and, optionally, recombining said dissolved ammonia with said ultrapure main flow and directing said dissolved ammonia to a dissolved ammonia conduit to form a dissolved ammonia output.

8. The method of claim 7, further comprising outgassing the carrier gas to produce one or more gas outputs.

9. The method of claim 7, wherein the ammonia gas being directly diluted in the ultrapure water bypass flow away from a nitrogen saturation area.

10. The method of claim 7, wherein the ultrapure water flow reacting with the ammonia within the carrier gas bubbles to form the highly soluble ammonia gas dissolving within the ultrapure water flow.
